(19) United States
(12) Patent Application Publication
(10) Pub. No.: US 2023/0408353 A1
(43) Pub. Date: Dec. 21, 2023

(54) METHOD FOR PRODUCING A DEFORMATION BODY FOR MEASURING A FORCE AND/OR A TORQUE FOR A ROLL STABILIZATION SYSTEM FOR A VEHICLE, AND DEFORMATION BODY

(71) Applicant: ZF Friedrichshafen AG, Friedrichshafen (DE)

(72) Inventor: Georg Tenckhoff, Altshausen (DE)

(73) Assignee: ZF Friedrichshafen AG, Friedrichshafen (DE)

(21) Appl. No.: 18/252,257

(22) PCT Filed: Oct. 11, 2021
(86) PCT No.: PCT/EP2021/077976

§ 371 Date: May 9, 2023

(30) Foreign Application Priority Data
Nov. 13, 2020 (DE) 10 2020 214 282.3

(51) Int. Cl. G01L 3/10; G01L 1/12; H10N 35/00

(52) U.S. Cl. CPC G01L 3/102; G01L 1/125; H10N 35/101

(57) ABSTRACT

A method is proposed for the production of a deformation body (100) for measuring a force and/or a torque for a roll stabilization system of a vehicle. In one example, the method comprises a step of preparing a support material, a step of producing a central element (104) that can be connected to the support material and can be deformed by the force, and a step of connecting the support material to the central element (104) in order to produce the deformation body (100).

### RELATED APPLICATIONS

This application claims the benefit under 35 U.S.C. § 371 as a U.S. National Phase Application of application no. PCT/EP2021/077976, filed on 11 Oct. 2021, which claims benefit of German Patent Application no. 10 2020 214 282.3, filed 13 Nov. 2020, the contents of which are hereby incorporated herein by reference in their entireties.

### FIELD OF THE DISCLOSURE

The present invention relates to a method for producing a deformation body for measuring a force and/or a torque for a roll stabilization system of a vehicle, and to a deformation body.

### BACKGROUND

EP 3 315 933 B1 describes a magnetostrictive sensor, a magnetic structure, and a production method for them, as well as a motor drive unit with a magnetostrictive sensor and a motor-assisted bicycle.

### SUMMARY

Against that background, the present invention provides an improved method for producing a deformation body for measuring a force and/or a torque for a roll stabilization system of a vehicle and an improved deformation body. Advantageous design features will be apparent from the description given below.

Thanks to the approach presented herein, a deformation body can advantageously be produced for force and torque measurement and whose elastic behavior under load can be measured. In this way, conflicts of interest between production ability, price, material costs, determined material properties, shaping, weldability, and availability of the semifabricate can be avoided. Accordingly, a method is proposed for producing a deformation body for measuring a force and in addition or alternatively a torque for a roll stabilization system of a vehicle. The method in this case comprises a step of preparing a support material, a step of producing a central element that can be connected to the support material and can be deformed by the force, and a step of connecting the support material to the central element in order to produce the deformation body.

In one example, the deformation body can be used as a torsion element of a roll stabilization system. The deformation body can be arranged between a first stabilizer element and a second stabilizer element. Such a system makes it possible to provide stabilizing torques at a front axle and in addition or alternatively at a rear axle of the vehicle, so that a rolling movement of the vehicle body is minimized or completely eliminated. The deformation body can be a component suitable for force transmission. During the operation of the deformation body it can deform, for example, if the torque or the forces act upon the support material or a support element made from it. The central element can absorb these forces and, as a function of that, it can also be deformed so as to serve as a sensor. The method proposed here now enables the central element to be fixed securely onto the support material in order to ensure perfect operation of the deformation body during the force and torque measurement. Such secure attachment can be realized, for example, if the deformation body is made in segmented form or by powder-metallurgical means. For example, the support material can be a granulate or at least partially made from a granulate. The central element can for example be in the form of an inlay inserted in or attached onto the support material.

According to an embodiment, in the production step the central element can be made by injection-molding, press-forming, 3D-printing, flame-spraying, hot-spraying, and in addition or alternatively by sintering. The injection-molding can for example be carried out by a MIM (Metal Injection Molding) process, i.e., by means of metal powder injection molding. The sintering can be carried out, for example, as selective laser sintering (SLS). By one or a combination of several such production methods, any desired shape can be produced for the central element. Depending on its method of production the central element is also called a green compact.

In an embodiment, in the connection step the support material and the central element can be joined to one another by injection-molding.

Advantageously, the support material and the central element are joined by MIM injection-molding. In that way, a secure, for example, durable or even permanent connection between the support material and the central element can be produced.

Furthermore, in the connection step the support material and the central element are joined to one another by solid-body welding, flame-spraying, and additionally or alternatively by sintering. The solid-body welding advantageously can consist in diffusion welding, friction stir welding, and in addition or alternatively ultrasonic welding.

According to an embodiment, in the production step the central element can be made as a sensor element. In that way, the torque can be determined advantageously.

In the connection step, the central element can be joined to the support material in such manner that at least one side of the central element contacts at least one further side of the support material. For example, the support material can be made in one or more pieces. Thus, a good mechanical joint can be made between the central element and the support material.

In an embodiment, in the connection step the central element can be arranged on an inside wall or on an outside wall. In addition, or alternatively, the central element can be arranged between a plurality of part-sections of the support material. This means that the central element can for example be arranged on a wall of the support material but also, for example, centrally in the support material. This enables great flexibility in relation to design.

The central element can be made in the shape of a ring. In that case the support material can also be made annular. This enables the shaping of a segmented, tubular deformation body. During the operation of the deformation body, in that way the force or torque can be transmitted and thereby sensed, by way of the central element, from one end of the deformation body to an opposite end of the deformation body.

According to an embodiment, the central element can be made in a herringbone-like pattern. By virtue of such a pattern, a plurality of webs can be formed, whose separation or orientation can change during a deformation of the central element. The webs can for example be in the shape of a condenser device. In that way the deformation of the central element can be reliably recognized.

In an embodiment, the central element can be X-shaped. Advantageously, the X-shape enables good force transfer into the central element.

The method can comprise a step of forming the support material before the step of preparing the support material, such that in the step of forming, the support material is formed using a basis material and a binder. The basis material can be, for example, a metal powder and the binder can be, for example, a plastic binder.

In an embodiment, in the connection step the support material can be shaped at least partially in the form of a cylinder in order to obtain a support element. For example, the support element can be in the shape of a hollow cylinder.

According to an embodiment, in the production step the central element can be made using at least a magnetostrictive material and a binder. The magnetostrictive material can advantageously be in the form of a different metal powder. Advantageously, the magnetostrictive material can have sensory or for example electrically conducting properties.

Furthermore, a deformation body for measuring a force and in addition or alternatively a torque for a roll stabilization system of a vehicle is proposed. In this case the deformation body comprises a support element and a central element that is joined to the support element and can be deformed by the force. This, therefore, can be a segmented deformation body.

The deformation body can advantageously be made in the form of a shaft, which can be deformed in two opposite directions. Such a shaft can be used as a torsion element of a roll stabilizer.

According to an embodiment, the central element can have at least an adapter structure and a sensory inlay arranged on the adapter structure. The adapter structure, for example, can be or is made by a welding method. Such an adapter structure can serve to attach the inlay to the support element. The inlay can be shaped so as to sense the force introduced by the adapter structure.

### BRIEF DESCRIPTION OF THE DRAWINGS

An example of the invention is explained in greater detail with reference to the attached drawings, which show:

FIG. 1: A schematic representation of a deformation body, according to an example embodiment;

FIG. 2: A schematic representation of a deformation body, according to an example embodiment;

FIG. 3: A schematic representation of a deformation body, according to an example embodiment;

FIG. 4: A schematic representation of a deformation body, according to an example embodiment;

FIG. 5: A schematic partial representation of a deformation body, according to an example embodiment;

FIG. 6: A schematic cross-sectional representation of a welded section of a deformation body, according to an example embodiment;

FIG. 7: A schematic cross-sectional representation of a section of a deformation body to be press-formed, according to an example embodiment;

FIG. 8: A flow chart of a method according to an example embodiment, for producing a deformation body for measuring a force and/or a torque for a roll stabilization system of a vehicle;

FIG. 9: A flow chart of a method according to an example embodiment, for producing a deformation body for measuring a force and/or a torque for a roll stabilization system of a vehicle; and

FIG. 10: A schematic representation of a vehicle with a roll stabilizer system comprising a deformation body according to an example embodiment.

### DETAILED DESCRIPTION

In the following description of preferred example embodiments of the present invention, the same or similar indexes are used for elements in the various figures that have similar functions, so obviating the need for repeated descriptions of the said elements.

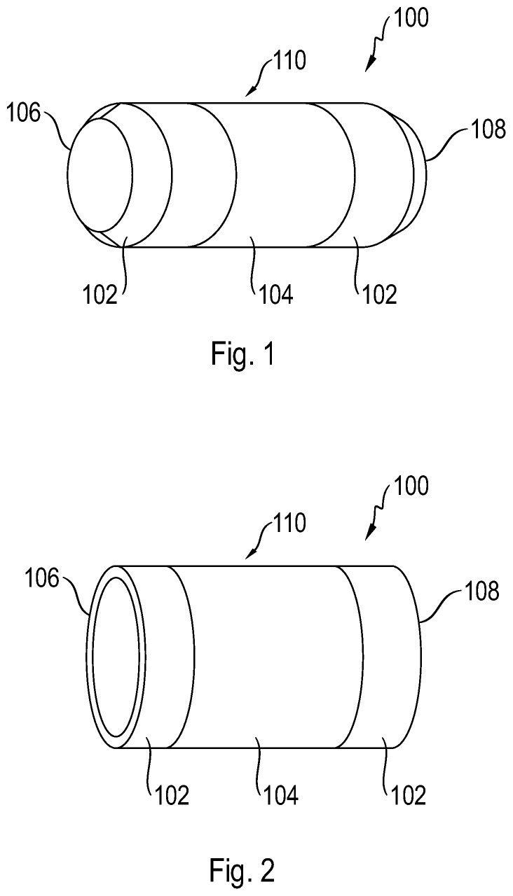

FIG. 1 shows a schematic representation of a deformation body 100 according to an example embodiment. In this example embodiment, the deformation body is designed to transmit a force and/or a torque. The deformation body 100 can also be used to measure, or at least to detect the force and/or torque.

In this example embodiment, the deformation body 100 is in the form of a shaft, which comprises a support element 102 and a central element 104. The central element 104 is firmly connected to the support element 102, for example in a material-merged manner, and is designed to be deformed. In this example embodiment the deformation body 100 is made in three parts. This means that in this example embodiment the support element 102 consists of a number of part-sections, which are arranged on or around the central element 104. Both the support element 102 and the central element 104 are ring-shaped. In this example embodiment the deformation body 100 is shaped at least in part as a cylinder, or more precisely a hollow cylinder. A first end 106 and a second end 108 of the deformation body 100 have in this example embodiment a smaller diameter that the main part 110 of the deformation body 100.

The central element 104 serves not only to transmit force between the adjacent part-sections of the support element 102, but also to determine the force transmitted or a deformation resulting therefrom. Thus, the central element 104 is designed to be a sensor element or part of a sensor element. In an example embodiment the central element 104 is in the form of a magnetostrictive inlay. When the central element 104 is designed not only to detect the force or torque but also to measure them, then according to an example embodiment, the central element 104 is designed to emit a sensor signal that indicates the force and/or the torque. The sensor signal is used, for example, by a control unit of the roll stabilization system to control the rolling behavior of the vehicle.

In an alternative example embodiment, the central element 104 is for example in the form of a layer applied on a one-piece support element 102.

According to an example embodiment the deformation body 100 is used for force and/or for torque measurement. During this the elastic behavior of the deformation body 100 under load can be measured. In an example embodiment the central element 104 is in the form of a magnetostrictive measurement body. A corresponding measurement principle as a rule requires high contents of carbon C, nickel Ni, chromium Cr and cobalt Co. This conflicts with the requirement of good welding properties, which is desirable as a joining method for adjacent components in series applications. By virtue of the approach described herein, this problem is advantageously circumvented. For that purpose, the deformation body 100, also referred to as a shaft, has three segments in this example embodiment, two of the segments forming the support element 102 and the third segment corresponding to the central element 104. In this example embodiment the support element consists for example of a thermally weldable material and the central element 104 consists of a material with good sensory properties. The connection is produced for example by a solid-body welding method such as diffusion welding, friction stir welding and/or ultrasonic welding, applied to the, for example, separately produced segments or, however, particularly advantageously, by sintering at least one powder applied by powder-metallurgical means.

FIG. 2 shows a schematic representation of a deformation body 100 according to an example embodiment. The deformation body 100 shown in this case can correspond or be similar to the deformation body 100 described in FIG. 1. In this example embodiment the deformation body 100 is tubular. This means that compared with the deformation body 100 described in FIG. 1, the first end 106 and the second end 108 differ in having the same diameter as the main body 110 itself. In this example embodiment too the deformation body 100 comprises a support element 102 and a central element 104.

In other words, the tubular shape of the deformation body 100 shown here is advantageous for an electro-mechanical roll stabilization system (ERC). For example, an unfavorable wall thickness in relation to the diameter and length ratio is ignored when, for example, a so-termed MIM (Metal Injection Molding metal powder in a plastic binder matrix) production method is used. In an alternative example embodiment, the deformation body 100 can be used as a force and torque measurement sensor system in connection with a so-termed “Road Load Weighting”, i.e., a road load measurement method.

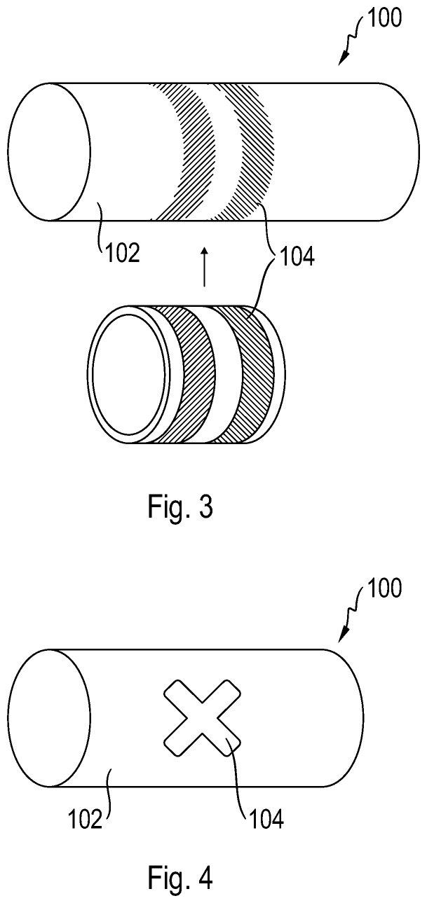

FIG. 3 shows a schematic representation of a deformation body 100 according to an example embodiment. The deformation body 100 shown in this case can correspond, or at least be similar to the deformation body described in either of FIG. 1 or 2. In this example embodiment, the support element 102 is made in one piece and the central element 104 is in the form of an annular inlay with a herringbone pattern. In this example embodiment, the deformation body 100 also is tubular. The central element 104 can be made, for example, flush with a surface of the support element 102.

In other words, complex inlays, in other words central elements 104 in accordance with this example embodiment, can be shaped from a weldable material and sintered for example to produce a metallic and/or mixed ceramic deformation body 100. Advantageously the delicate structure, for example a supporting web, can be applied inexpensively and/or flush onto a surface.

FIG. 4 shows a schematic representation of a deformation body 100 according to an example embodiment. The deformation body 100 shown in this case can correspond, or at least be similar to the deformation body 100 described in any of FIGS. 1 to 3. In this example embodiment the support element 102 is made in one piece and the central element 104 is X-shaped. According to this example embodiment the central element 104 is arranged in or on an outer wall of the support element 102. In an alternative example embodiment, the central element 104 is arranged in or on an inner wall of the support element 102 opposite the outer wall and facing toward a hollow space of the support element 102. Thanks to this shape of the central element 104 deformations of the deformation body 100 are easier to recognize.

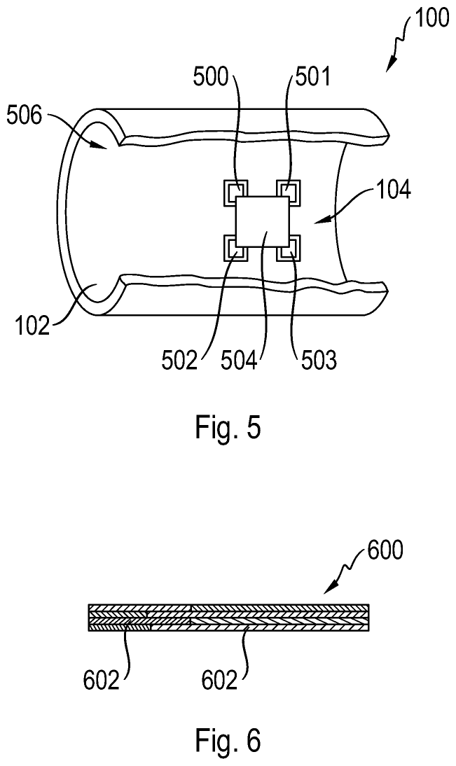

FIG. 5 shows a schematic partial representation of a deformation body 100 according to an example embodiment. The deformation body 100 shown in this case can correspond, or at least be similar to, the deformation body 100 described in any of FIGS. 1 to 4. The difference is that the central element 104 shown here has at least one adapter structure 500, 501, 502, 503 and a sensory inlay 504. The sensory inlay 504 in this example embodiment is for example rectangular and is fixed onto the at least one adapter structure 500, 501, 502, 503.

According to this example embodiment the central element 104 has a total of four adapter structures 500, 501, 502, 503, which in this example embodiment are each rectangular in shape and are arranged in a rectangle on an inner wall 506 of the support element 102.

According to an example embodiment, the sensory inlay 504 is shaped so as to detect a force introduced by way of the adapter structure 500. The shape and arrangement shown and the number of adapter structures 500, 501, 502, 503 have in this case been chosen only as an example and can be adapted in accordance with the shape of the sensory inlay 504 and the type of force introduction desired.

FIG. 6 shows a schematic cross-sectional representation of a welded section 600 of a deformation body according to an example embodiment. For example, the section 600 can correspond to or can be similar to an interface between the support element and the central element as described in any of FIGS. 1 to 5. The section 600 can also be part of a support element or a central component.

In this example embodiment, the section 600 has a plurality of layers 602 or laminations, which are joined together, for example, by ultrasonic welding.

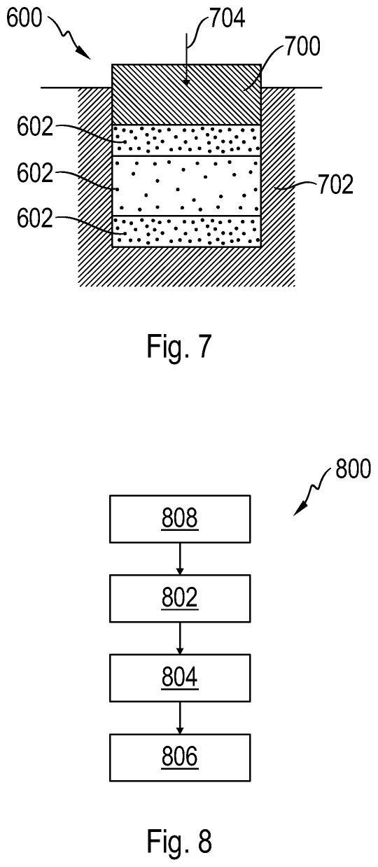

FIG. 7 shows a schematic cross-sectional representation of a section 600 of a deformation body 100 to be press-formed, according to an example embodiment. For example, the section 600 can correspond to or can be similar to the section 600 described in FIG. 6. In this example embodiment, here too the section 600 comprises a plurality of layers 602. The section 600 is produced using a ram 700 and a die 702. The arrow 704 shown here shows a force direction in which the layers 602, which according to an example embodiment are powder layers, are pressed together in order to produce, for example, a so-termed green compact.

FIG. 8 shows a flow chart for a method 800 according to an example embodiment, for producing a deformation body for measuring a force and/or a torque for a roll stabilization system of a vehicle. By means of the method 800, for example, a deformation body can be produced, such as those described in any of FIGS. 1 to 5, for example, and having a section such as those described in FIG. 6 or 7. The method 800 has a step 802 of preparing a support material, a production step 804, and a connection step 806. In the step 802 of preparing a support material a support material is prepared. In the production step 804 the central element is made, which can be joined to the support material and can be deformed by the force. In the connection step 806 the support material is joined to the central element in order to produce the deformation body. In this example embodiment, the support element is made from the support material.

Optionally, the method 800 has a step 808 of forming the support material before the step 802 of preparing the support material. According to an example embodiment, in the said formation step 808 the support material is made from at least one basis material and a binder. The basis material is for example a metal powder which for example has good welding properties. Also optionally, in the production step 804 the central element is made as a sensor element. In this example embodiment, the central element is for example made in a ring shape and/or in a herringbone pattern. Alternatively, in the production step 804 the central element is made to be X-shaped. For this, for example, the central element is produced using at least one magnetostrictive material and a binder. The magnetostrictive material is in this case, for example, a metal powder with sensory properties. The central element is, for example, produced by injection-molding, for example by the so-termed MIM (Metal Injection Molding) process, by press-forming, by 3D-printng, flame-spraying, hot-spraying, and/or by a sintering method such as selective laser sintering (SLS). In this example embodiment, in the connection step 806 the support material is at least in part shaped cylindrically, for example, as a hollow cylinder. In this example embodiment, in the connection step 806 the central element is joined to the support material, preferably by injection-molding (MIM) but alternatively also by solid-body welding, such as diffusion welding, friction stir welding, and/or ultrasonic welding, flame-spraying and/or sintering. In the connection step 806 the central element is joined to the support material in such manner that at least one side of the central element is in contact with at least a further side of the support material. This means that the support element is optionally made integrally or in several parts. Corresponding to the particular formation of the support element, in the connection step 806 the central element is arranged for example on an inner wall, on an outer wall, or between a plurality of part-sections of the support material.

Expressed in other words, in the method 800 presented here the deformation body is produced in segmented form and/or by powder-metallurgical means. In this example embodiment the edge segments, i.e., the support element is made from a weldable material. For example, the central element, also called the middle part, is made as an “inlay.” In this example embodiment the central element is made from a material with advantageous sensor properties, in particular magnetostrictive properties.

In this example embodiment the support element and the central element are produced either by solid-body welding of a plurality of segments, among which, for example, there can also be metal foils, or by sintering a suitable die-pressed blank made from appropriate metal powders, since as a rule thermal welding cannot be used because of the material pairing. In an example embodiment, the die-pressed blank contains at least two metal powders or, alternatively, mixtures of metal powders with other desired materials, such as ceramics, alloying additions, and/or binders.

Generative production methods, too, such as “3D printing”, SLS, flame- and/or heat-spraying, are conceivable for achieving the desired internal structure of the material. For example, in this context not only the functional aspects but shape-imparting aspects as well are taken into account, and holders, receptacles, ribs, perforations, holes, threads and suchlike can be produced. The method 800 proposed herein is particularly to be considered for the production of a hollow shaft and/or a cover of the ERC system. For this, hot-spraying, flame-spraying, and plasma-spraying can be considered. In this, for example, a cooling rate is interesting to achieve a hardness and an amorphousness as advantageous properties for a magnetostrictive sensor system. Likewise, for example, a combination of magnetostrictive ceramic FeCoOₓ with a metal can be considered.

According to this example embodiment, the possibility of including patterns and/or structures of magnetostrictive material, such as powder, sheet, pressing blanks or inserts on the surface or on the inside of the deformation body is realized. A particular embodiment is, for example, a graduated or stepped transition at the boundaries of the material for more gentle conformity with the heat stresses. Alternatively, this can be achieved by an appropriate choice of material.

In summary, in the method 800 according to this example embodiment, a selective combination of two or more materials is processed by a solid-body, diffusion and/or sintering method to produce a measurement body, in this context called a deformation body, for a magnetostrictive force or torque measurement process, with at least one area that has advantageous sensory properties, and areas which are suitable for joining to adjacent components by thermal welding processes. Advantageously, sintering, flame spraying, ultrasonic or diffusion welding are also economically interesting production methods for large production runs. By virtue of the method 800, a segmented or powder-metallurgically made deformation body can be produced.

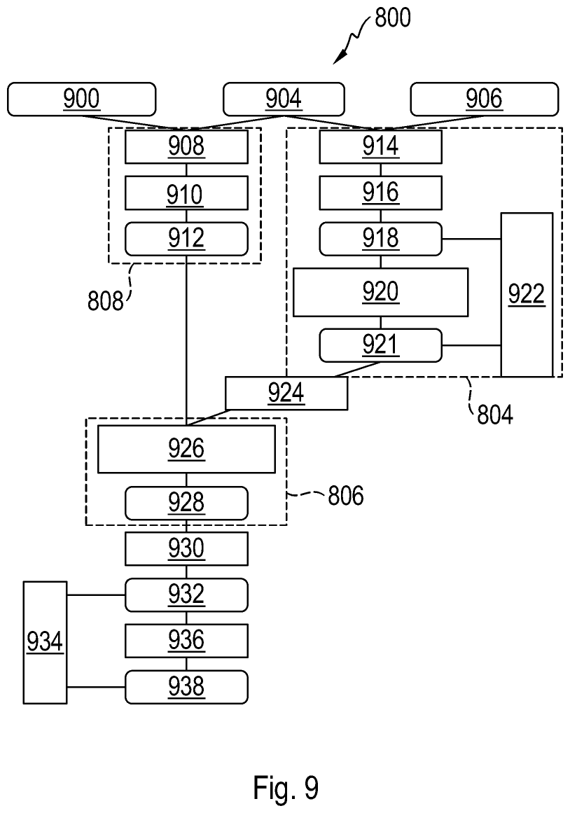

FIG. 9 shows a flow chart for a method 800 according to an example embodiment, for making a deformation body for measuring a force and/or a torque for a roll stabilization system of a vehicle. The method 800 can correspond to or can be similar to the method 800 described in FIG. 8. In this example embodiment the method 800 is only described in more detail than in FIG. 8.

According to this example embodiment, the method 800 includes a step 900 of preparing a basis material, a step 904 of preparing the binder and a step 906 of preparing the magnetostrictive material, before the step 808 of forming the support material. In this example embodiment, the formation step 808 includes a part-step 908 of mixing the basis material with the binder in order to obtain a mixture. Thereafter, the step 808 has a part-step 910 of granulating, using the said mixture, in order to obtain the support material, for example, in the form of a granulate which, later on in the process 800, is prepared as the granulate in a part-step 912 of preparation. In this example embodiment, the production step 804 also includes a plurality of part-steps. In one part-step 914 of mixing, the magnetostrictive material is mixed with the binder in order to obtain a further mixture. In a part-step 916 of further granulation, using the said further mixture, a further granulate is obtained and in a part-step 918 of preparation the said further granulate is prepared. In a part-step 920 of injection-molding the central element is made, which at this time can for example also be called a green compact, and in a part-step 921 of preparation the green compact is prepared. For example, in the event of a defective pressing, in a recovery part-step 922 the defective pressing is extracted and, for example, during a subsequent production of a further deformation body, it is used again.

According to this example embodiment the method 800 further comprises a step 924 of inlaying, in which the central element is set into a die in order, then, in the connection step 896, to be joined to the support material. In this example embodiment the connection step 806 contains a part-step 926 for further injection-molding in order to obtain another green compact which, in a preparation part-step 928, is prepared as the further green compact. Thereafter the method 800 optionally comprises a step 930 of release in which, according to this example embodiment, the binder 904 is expelled from the further green compact in order to obtain a so-termed brown compact which, in a step 932 of preparation, is prepared as the brown compact. The method 800 comprises an optional step 934 of finish processing, which comprises a part-step 936 of sintering in which the brown compact is cured in such manner that the deformation body is obtained as a finished end-product and, in a preparation step 938, is provided as a finished end-product.

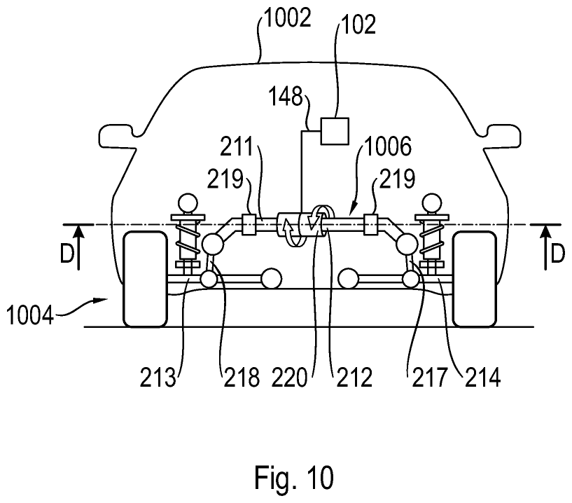

FIG. 10 shows a schematic cross-sectional representation of an electro-mechanical roll stabilization system 1000 according to an example embodiment. This can be the roll stabilization system 1000 mentioned in FIG. 1, with a deformation body 100 as described in any of FIGS. 1 to 5. The vehicle 1002 can also be the vehicle 1002 described in FIG. 1.

The purely schematic representation sows a section through the vehicle 1002, along a vertical axis and a transverse axis of the vehicle 1002. For example, a first axle 1004 is shown with a first example embodiment of a roll stabilization device 1006 of the roll stabilization system 1000, also called the stabilizer. The roll stabilization device 1006 in this example embodiment is made in the form of a two-part torsion bar with a first stabilizer element 1008 and a second stabilizer element 1010. In this case one end of the first stabilizer element 1008 is connected to a first wheel suspension element 1012 of the vehicle 1002, and one end of the second stabilizer element 1010 is connected to a second wheel suspension element 1014 of the vehicle 1002.

For example, the ends of the stabilizer elements 1008, 1010 are in this case in the form of arms preferably bent or offset approximately in the travel direction, which are respectively connected with the wheel suspension elements 1012, 1014 by way of the articulated pendulum supports 1016, 1018. The wheel suspension elements 1012, 1014 are for example opposite transverse control arms of the vehicle 1002. The stabilizer elements 1008, 1010 are in each case fixed by means of a build-up bearing 1020, rotatably about a common rotation axis D-D, on a chassis or onto the body of the vehicle 1002. In this case, for example, the rotation axis D-D corresponds to the transverse axis of the vehicle 1002.

In each case an end of the stabilizer elements 1008, 1010 facing toward the middle of the vehicle 1002 is mechanically coupled to at least one electric motor of a three-phase current drive device 1022 that serves as an actuator. The three-phase current drive device 1022 is designed, when it receives a control signal 1024 from a control unit 1026, to rotate the stabilizer elements 1008, 1010 in opposite directions about the rotation axis D—D. Here, for example, the control signal 1024 represents a signal determined on the basis of a field-orientated regulator. By virtue of the opposite rotations of the stabilizer elements 1008, 1010, the wheel suspension elements 1012, 1014 are moved in such manner as to counteract rolling of the vehicle body, for example when driving round a curve. In an example embodiment the vehicle 1002 is equipped with the control unit 1026, which is connected to the three-phase current drive device 1022 and is designed to emit the control signal 1024.

The vehicle 1002 can also comprise at least a second electro-mechanical roll stabilization system, which can be designed in the same way as the roll stabilization system 1000. Alternatively, an alternative roll stabilization principle can be used. For example, the stabilizer elements 1008, 1010 can be omitted if the counter-roll torque is applied using suitable actors in the wheel suspension elements 1012, 1014.

### INDEXES

100 Deformation body
102 Support element
104 Central element
106 First end
108 Second end
110 Body
500, 501, 502, 503 Adapter structure
504 Sensory inlay
596 Inner wall
600 Section
602 Layer
700 Ram
702 Die
704 Arrow
800 Method
802 Step of preparing a support material
804 Production step
806 Connection step
808 Forming step
900 Step of preparing a basis material
904 Step of preparing the binder
906 Step of preparing the magnetostrictive material
908 Mixing part-step
910 Granulating part-step
912 Part-step of preparing the granulate
914 Mixing part-step
916 Further granulation part-step
918 Part-step of preparing the further granulate
920 Injection-molding part-step
921 Part-step of preparing the green compact
922 Recovery part-step
924 Inlaying step
926 Further injection-molding part-step
928 Part-step of preparing the further green compact
930 Releasing step
932 Step of preparing the brown compact
934 Finish-processing step
936 Sintering part-step
938 Step of preparing the finished end-product
1000 Roll stabilization system
1002 Vehicle
1004 First axle
1006 Roll stabilization device
1008 First stabilizer element
1010 Second stabilizer element
1012 First wheel suspension element
1014 Second wheel suspension element
1016 Pendulum support
1018 Pendulum support
1020 Build-up bearing
1022 Three-phase current drive device
1024 Control signal
1026 Control unit
D—D Rotation axis

1. Method (800) for producing a deformation body (100) for the measurement of a force and/or a torque for a roll stabilization system (1000) of a vehicle (1002), wherein the method (800) comprises:
preparing (802) a support material;
producing (804) a central element (104) configured to be joined to the support material and can be deformed by the said force and/or torque; and
joining (806) the support material to the central element (104) in order to make the deformation body (100).

2. The method (800) according to claim 1, wherein producing (804) the central element (104) is performed by injection-molding, pressing, 3D-printing, flame-spraying, hot-spraying, and/or sintering.

3. The method (800) according to claim 1, wherein joining the support material (806) to the central element (104) is performed by injection-molding.

4. The method according to claim 1, wherein joining (806) the support material to the central element (104) is performed by solid-body welding, flame-spraying, and/or sintering.

5. The method (800) according to claim 1, wherein producing the central element (104) is performed such that the central element is configured as a sensor element.

6. The method (800) according to claim 1, such that in the joining (806) the central element (104) to the support material is performed in such manner that at least one side of the central element (104) is in contact with at least one further side of the support material.

7. The method (800) according to claim 1, wherein joining (806) the support material to the central element (104) includes arranging the central element (104) on an inside wall (506) or on an outer wall or between a plurality of part-sections of the support material.

8. The method (800) according to claim 1, wherein producing (804) the central element (104) is performed to result in the central element having an annular shape.

9. The method (800) according to claim 1, wherein producing (804) the central element (104) is performed to result in the central element having a herringbone pattern.

10. The method (800) according to claim 1, wherein producing (804) the central element (104) is performed to result in the central element having an X-shape.

11. The method (800) according to claim 1, comprising:
forming (808) the support material before preparing (802) the support material, and forming (808) the support material is includes using at least one basis material and a binder.

12. The method (800) according to claim 1, wherein joining (806) the support material to the central element includes providing the support material having, at least in part, a cylindrical shape.

13. The method (800) according to claim 1, wherein producing (804) the central element (104) includes using at least one magnetostrictive material and a binder.

14. A deformation body (100) for measuring a force and/or a torque for a roll stabilization system (1000) of a vehicle (1002), wherein the deformation body (100) comprises:
a support element (102); and
a central element (104) connected to the support element (102) and can be deformed by the force and/or the torque.

15. The deformation body (100) according to claim 14, wherein the central element (104) comprises at least one adapter structure (500, 501, 502, 503) and a sensory inlay (504) arranged on the adapter structure (500, 501, 502, 503).
